(19) United States
(12) Patent Application Publication
(10) Pub. No.: US 2010/0117523 A1
(43) Pub. Date: May 13, 2010

(54) SUBSTRATE BEARING A DISCONTINUOUS ELECTRODE, ORGANIC ELECTROLUMINESCENT DEVICE INCLUDING SAME AND MANUFACTURE THEREOF

(75) Inventor: Svetoslav Tchakarov, Arcueil (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: Saint-Gobain Glass France, Courbevoie (FR)

(21) Appl. No.: 12/527,723

(22) PCT Filed: Feb. 25, 2008
(86) PCT No.: PCT/FR08/50313

§ 371 Date: Dec. 22, 2009

(30) Foreign Application Priority Data
Feb. 23, 2007 (FR) 0753453

(51) Int. Cl. H01J 1/62; H01J 1/88; H01J 9/14; H01J 9/00

(52) U.S. Cl. 313/504; 313/291; 445/52; 445/23

(57) ABSTRACT

The subject of the invention is a substrate for an organic light-emitting device (10) bearing a discontinuous electrode (2a to 2″c) having a metallic functional layer having an intrinsic electrical conductivity property, between a contact layer and an overlayer, the electrode having a surface resistance equal to or less than 5 Ω/□ for a functional layer thickness of less than 100 nm, the electrode being in the form of at least one row of electrode zones, each electrode zone having a first dimension (l) of at least 3 cm in the direction (X) of said row, the electrode zones of each row being spaced apart by what is called the intra-row distance (d1), this being equal to or less than 0.5 mm. The subject of the invention is also an organic light-emitting device (10) incorporating this electrode and the fabrication of this electrode and of this device.

The subject of the present invention is a substrate bearing a discontinuous electrode for an organic light-emitting device, the organic light-emitting device incorporating it, and their fabrication.

Organic light-emitting systems or devices (OLEDs) comprise an organic electroluminescent material or a stack of such materials supplied with electricity by electrodes flanking it in the form of electroconductive layers.

Conventionally, the upper electrode is a reflective metal layer, for example made of aluminium, and the lower electrode is a transparent layer based on indium oxide, generally tin-doped indium oxide known more by the abbreviation ITO, with a thickness of around 100 to 150 nm. However, this ITO layer has a number of drawbacks. Firstly, the material and the high-temperature (350° C.) deposition process for improving the conductivity incur additional costs. The surface resistivity remains relatively high (of the order of 10 Ω/□ unless the thickness of the layers is increased to greater than 150 nm, thereby resulting in a reduction in transparency and an increase in the surface roughness, creating spike effects that drastically reduce the lifetime and the reliability of the OLED.

Furthermore, to electrically separate the electrodes, the lower electrode is discontinuous, typically forming parallel bands of electrodes, each illuminating band being connected in series. Now, the Applicant has found that it is not possible to have uniform illumination on illuminating bands of large area. Furthermore, to obtain a satisfactory fill factor, corresponding to the ratio of illuminating area to total area of the device, it is necessary for the distance between the electrode bands to be drastically reduced using expensive photolithography techniques.

Document EP1 521 305 thus provides a lower ITO-based electrode in the form of zones of series-connected electrodes separated by etching lines that are invisible to the naked eye and filled with an insulating material, this being deposited by photolithography.

In other known devices, the upper electrode is a continuous reflective electrode and the lower electrode is a continuous ITO layer surmounted by metal lines, generally made of aluminium, and optionally organized in a grid, these metal lines aiming to improve the electroconductivity properties of the ITO layer for more uniform illumination over large areas. To obtain a satisfactory fill factor, these lines are fine, with a width of the order of 100 μm, and are obtained by photolithography with a mask made of a photosensitive resin or photoresist, typically with a thickness of about 400 nm. This photoresist is preserved on the lines for the purpose of passivation, so as to prevent short circuits between the lower electrode and the upper electrode.

This lower electrode is expensive and lacks reliability since a single short-circuit point contaminates the entire area, making the light-emitting device defective.

The object of the invention is to obtain a lower electrode which, while still ensuring uniformity of illumination over large areas and having a satisfactory fill factor, is reliable, less expensive and preferably easy to fabrication, especially on an industrial scale.

For this purpose, one subject of the present invention is a substrate, for an organic light-emitting device, bearing on a main face of a discontinuous electrode comprising in succession, starting from the substrate:
a contact layer based on a single or mixed doped or undoped metal oxide;
a metallic functional layer having an intrinsic electrical conductivity property, based on silver, the functional layer thickness being less than 100 nm; and
a work-function-matching overlayer, based in particular on a simple or mixed, doped or undoped metal oxide, the electrode having a surface resistance equal to or less than 5 Ω/□, or even equal to or less than 4 Ω/□ for a functional layer thickness of less than 100 nm, preferably equal to or less than 50 nm.

The discontinuous electrode according to the invention is additionally in the form of at least one row of electrode zones, with electrode zones (preferably all zones) having a first dimension of at least 3 cm, and preferably at least 5 cm, in the direction of said row, the electrode zones of the row being spaced apart by what is called the intra-row distance, this being equal to or less than 0.5 mm.

Furthermore, insulating material fills the space between the electrode zones of the row (and preferably, if appropriate, the space of any adjacent rows) and extends beyond the electrode zones.

The electroconductive properties of the electrode according to the invention are made possible by the choice of a multilayer stack having a silver-based functional layer, this also being less expensive than an ITO functional layer, and by the nature of the electrode material and the fabrication, which can be carried out at ambient temperature, for example by spraying or evaporation.

The electroconductive properties allow uniformity of illumination for each illuminating zone defined by the chosen electrode zones that are relatively extended (at least 3 cm), without jeopardizing the transparency or generating roughness, the functional layer thickness being limited.

Typically, for an illuminating zone associated with an electrode zone or for several or each of such illuminating zones, the ratio between the brightness (measured in Cd/m²) at the centre of this illuminating zone to any edge thereof may thus be equal to or greater than 0.7, or more preferably equal to or greater than 0.8.

The passivation via the insulating material prevents short circuits between the electrodes of the OLED. Furthermore, a resin covers the possibly irregular edges of the electrode zones. These covered zones are therefore not illuminating, thereby increasing the possibility of uniform illumination. However, for a satisfactory fill factor, the width of each covered border may preferably be less than 100 μm, or even less than or equal to 50 μm, for example between 10 and 30 μm.

The upper limit of the intra-row distance and the extent of each electrode zone ensures a high fill factor without having to have recourse to photolithography to create the electrode zones.

Since the electrode is organized in one or more rows, a defective electrode zone does not disturb the operation of the other electrode zones.

The total thickness of ITO, or of predominantly indium-based oxide, in the electrode may be equal to or less than 40 nm or even 30 nm.

The total thickness of the electrode may be equal to or less than 250 μm, still more preferably 150 nm in order to facilitate light extraction.

The electrode according to the invention may cover a large area, for example an area equal to or greater than 0.02 mm² or even 0.5 m² or 1 m².

The intra-row distance may be at least 20 μm so as to limit short circuits between the edges, preferably between 50 μm and 250 μm, especially between 100 and 250 μm.

Advantageously, the discontinuous electrode may be obtained without photolithography, for example:
by laser etching, typically forming rolls;
and/or by undermasking;
and/or by chemical screen-printing using an etching paste, especially an acid-based paste, typically forming irregular edges which are wavy as a result of the meshes of the screen-printing screen,
   which techniques are fully developed for industrial conditions and are inexpensive.

The undermasking consists in depositing the discontinuous mask, typically parallel lines optionally in the form of a grid. This mask is made of a material that can be dissolved by a solvent (water, alcohol, acetone, etc.) that is inert with respect to the electrode. The mask may be deposited by screen-printing or by ink jet. Next, a continuous layer of electrode material is deposited and the mask is dissolved, thus creating spaces between electrode zones (preferably in the form of parallel lines).

In a preferred design of the invention, the insulating material also covers the edges of the most peripheral electrode zones.

As insulating material, it is possible to choose for example an acrylic or polyamide resin, for example the resins Wepelan resins known as SD2154E and SD2954.

Preferably, to further reduce the fabrication costs, the preferably organic, in particular polymeric insulating material is chosen from screen-printed insulating material, especially an acrylic or polyamide resin, the insulating material being deposited by ink jet, for example, the ink described in the patent U.S. Pat. No. 6,986,982, or else deposited by roll coating.

The screen-printed insulating material typically forms irregular edges, which are wavy as a result of the meshes of the screen-printing screen. The material deposited by ink jet typically has a profile in the shape of coffee cups, the edges being broadened.

Preferably, for freedom of choice of the electrical connections, the electrode comprises a plurality of mutually parallel rows, the rows of electrode zones being spaced apart by an intra-row distance equal to or less than 0.5 mm, preferably between 100 μm and 250 μm.

These rows may preferably be electrically isolated from each other by an insulating resin, in particular such as the one described already, in particular screen-printed or deposited by ink jet.

Like the intra-row spaces, the spaces between rows may be preferably produced by laser or undermasking, by chemical screen-printing with etching paste.

Each electrode zone may be a full geometric (square, rectangular, round, etc.) pattern. From one row to another, the patterns may be offset, for example, for a staggered arrangement.

Within one and the same row, the electrode zones may be of essentially identical shape and/or size.

From one row to another, the electrode zones may be of essentially different shape and/or size.

In the direction perpendicular to the row, the electrode zone may have any size, for example at least 3 cm, 5 cm, or even some 10 cm (10 cm and beyond).

Advantageously, the electrode according to the invention may have:
a surface resistance equal to or less than 5 Ω/□ for each functional layer thickness equal to or less than 20 nm, and a light transmission T_{L} equal to or greater than 60%, more preferably 70%, and an absorption factor A (given by 1−R_{L}−T_{L}) of less than 10%, enabling it to be used as a particularly satisfactory transparent electrode for a bottom-emission light-emitting device;
a surface resistance equal to or less than 3 Ω/□ for each functional layer thickness above 20 nm, preferably equal to or less than 1.8 Ω/□, and a T_{L}/R_{L} ratio between 0.1 et 0.7 and an absorption factor A of less than 10%, enabling it to be used as a particularly satisfactory semi-transparent electrode for a bottom-emission and top-emission light-emitting device; and
a surface resistance equal to or less than 1 Ω/□ for each functional layer thickness above 50 nm, preferably equal to or less than 0.6 Ω/□, preferably combined with a light reflection R_{L} equal to or greater than 70%, even more preferably greater than 80%, thereby enabling it to be used as a particularly satisfactory reflective electrode for a top-emission light-emitting device.

The T_{L} may preferably be measured on a thin substrate, for example with a thickness of the order of 1 mm, for a T_{L} of about 90%, for example a soda-lime-silica glass.

The surface of the electrode may have an RMS roughness (also called R_{q}) preferably equal to or less than 2 nm and even more preferably equal to or less than 1.5 nm or even equal to or less than 1 nm so as to avoid spike effects.

The RMS roughness denotes the root mean square roughness. This is a measure of the RMS deviation of the roughness. This RMS roughness therefore specifically quantifies on average the height of the peaks and troughs of the roughness relative to the average height. Thus, an RMS roughness of 2 nm means a double peak amplitude.

It may be measured in various ways: for example, by atomic force microscopy, by a mechanical stylus system (using for example the measurement instruments sold by VEECO under the name DEKTAK) and by optical interferometry. The measurement is generally performed over an area of one square micron by atomic force microscopy and over a larger area, of around 50 microns by 2 millimetres, for mechanical stylus systems.

This low roughness is in particular achieved when the substrate comprises, between the base layer and the contact layer, a non-crystalline smoothing layer made of a mixed oxide, said smoothing layer being placed immediately beneath said contact layer and being made of a material other than that of the contact layer.

Preferably, the smoothing layer is a mixed oxide layer based on an oxide of one or more of the following metals: Sn, Si, Ti, Zr, Hf, Zn, Ga and In, and especially is an optionally doped mixed oxide layer based on zinc and tin or a mixed indium tin oxide (ITO) layer or a mixed indium zinc oxide (IZO) layer.

Preferably, the smoothing layer has a geometric thickness between 0.1 and 30 nm and more preferably between 0.2 and 10 nm.

The functional layer is based on pure silver or silver alloyed or doped with Au, Al, Pt, Cu, Zn, In, Si, Zr, Mo, Ni, Cr, Mg, Mn, Co, Sn or Pd. For example, Pd-doped silver or a copper/gold alloy or a silver/gold alloy may be mentioned.

It is possible to deposit the functional layer by a vacuum deposition technique, especially by evaporation or preferably by magnetron sputtering, especially at ambient temperature.

If a high conductivity is particularly sought, it may be preferable to choose a pure material. If remarkable mechanical properties are particularly sought, it may be preferable to choose a doped or alloyed material.

A silver-based alloy is chosen for its conductivity and its transparency. The thickness of the silver-based functional layer may be between 3 and 20 nm, preferably between 5 and 15 nm. Within this thickness range, the electrode remains transparent. The thickness of the silver-based functional layer may also be between 20 and 50 nm in order to switch from operation mainly in transmission to operation mainly in reflection.

The work-function-matching overlayer may have a work function Wf starting from 4.5 eV and preferably greater than or equal to 5 eV.

The work-function-matching overlayer may preferably be based on at least one of the following metal oxides: indium oxide, zinc oxide, molybdenum oxide and nickel oxide, which are preferably substoichiometric for matching the work function, aluminium oxide, titanium oxide, zirconium oxide, tantalum oxide, tin oxide and silicon oxide.

The metal oxide may be typically doped between 0.5 and 5%. In particular, it is S-doped tin oxide or zinc oxide doped with Al (AZO), Ga (GZO), B, Sc, or Sb for better stability of the deposition process and/or for increasing the electrical conductivity.

The overlayer may be based on a mixed oxide, in particular a generally non-stoichiometric mixed tin zinc oxide SnₓZn_{y}O_{z} having an amorphous phase or a mixed indium tin oxide (ITO) or a mixed indium zinc oxide (IZO).

The overlayer may be a monolayer or a multilayer. This layer preferably has a total thickness between 3 and 50 nm, more preferably between 5 and 20 nm.

It is preferable to choose an overlayer having an electrical conductivity greater than 10⁻⁶ S/cm, or even 10⁻⁴ S/cm, which layer is easy and/or rapid to produce and is transparent, especially a doped or undoped overlayer based on ITO, IZO, SnₓZn_{y}O_{z}, ZnO, NiOₓ, MoOₓ or In₂O₃.

Since this overlayer may preferably be the final layer, it is most particularly preferred to have an ITO overlayer that is stable and also allows the existing techniques for fabricating and optimizing the OLED organic structure to be retained, while still controlling the costs.

The substrate may preferably be flat.

The substrate may be transparent (in particular for emission through the substrate). The substrate may be rigid, flexible or semi-flexible.

Its main faces may be rectangular, square or of any other shape (round, oval, polygonal, etc.). This substrate may be of large size, for example with an area greater than 0.02 m² or even 0.5 m² or 1 m², and with an electrode occupying substantially the area (apart from the structuring zones).

The substrate may be a plastic, for example a polycarbonate, a polyethylene terephthalate PET, a polyethylene naphthalate PEN or a polymethyl methacrylate PMMA.

The substrate is preferably made of glass, especially a soda-lime-silica glass. Advantageously, the substrate may be a glass having an absorption coefficient of less than 2.5 m⁻¹, preferably less than 0.7 m⁻¹, at the wavelength of the OLED radiation.

For example, soda-lime-silica glasses with less than 0.05% Fe (III) or Fe₂O₃, are chosen, especially the glass DIAMANT from Saint-Gobain Glass, the glass OPTIWHITE from Pilkington, or the glass B270 from Schott. All the extra-clear glass compositions described in document WO 04/025334 may be chosen.

In a chosen configuration for emission of the OLED system through the thickness of the transparent substrate (bottom emission), part of the radiation emitted is guided in the substrate.

In addition, in an advantageous design of the invention, the thickness of the chosen glass substrate may be at least 0.35 mm, for example preferably at least 1 mm. This allows the number of internal reflections to be reduced and thus enables more of the radiation guided in the glass to be extracted, thereby increasing the brightness of the luminous zone.

The edges of the panel may also be reflective and preferably have a mirror, for optimum recycling of the guided radiation, and the edges form with the main face associated with the OLED system an external angle equal to or greater than 45°, preferably equal to or greater than 80°, but less than 90°, in order to redirect the radiation over a wider extraction area. The panel may thus be beveled.

The electrode may preferably include, beneath the functional layer, a base layer capable of forming a barrier to alkali metals.

The base layer can be a barrier to alkali metals lying beneath the electrode. It protects the contact layer, or any superjacent layer, from any contamination (which may result in mechanical defects, such as delaminations) and it also preserves the electrical conductivity of the functional metallic layer. It also prevents the organic structure of an OLED device from being contaminated by the alkali metals that in fact considerably reduce the lifetime of the OLED.

The migration of alkali metals may occur during fabrication of the device, resulting in a lack of reliability, and/or after fabrication, reducing its lifetime.

The base layer improves the bonding properties of the contact layer without appreciably increasing the roughness of the whole assembly, of the stack of layers, even when one or more layers are positioned between the base layer and the contact layer.

The base layer is preferably robust and easy and rapid to deposit using various techniques. It may for example be deposited by a pyrolysis technique, especially by CVD, (chemical vapour deposition). This technique is advantageous for the invention since appropriately adjusting the deposition parameters makes it possible to obtain a very dense layer as an enhanced barrier.

The base layer may optionally be doped with aluminium so as to make its vacuum deposition more stable. The base layer (optionally doped monolayer or multilayer) may have a thickness between 10 and 150 nm, and more preferably between 20 and 100 nm.

The base layer may preferably be:
a layer based on silicon oxide of general formula SiO),
a layer based on silicon oxycarbide (of general formula SiOC),
a layer based on silicon nitride (of general formula SiN), in particular based on Si₃N₄,
a layer based on silicon oxynitride (of general formula SiON),
a layer based on silicon oxycarbonitride (of general formula SiNOC).

It is possible for the nitriding of the base layer to be slight sub stoichiometric.

It may be based on silicon oxycarbide and with tin for reinforcement of the acid anti-etching properties in the case of chemical screen-printing.

A base layer essentially made of doped or undoped silicon nitride Si₃N₄ may most particularly be preferred. Silicon nitride is very rapidly deposited and forms an excellent barrier to alkali metals. Furthermore, thanks to its high optical index relative to the carrier substrate, it allows the optical properties of the electrode to be adapted by preferably varying the thickness of this base layer. Thus, it is possible for example to adjust the color in transmission when the electrode is transparent, or in reflection when the opposite face from the carrier substrate is a mirror.

The electrode may preferably include an etch stop layer especially for chemical etching, beneath the contact layer (or even on the optional and separate base layer), especially a layer based on tin oxide, this etch stop layer especially having a thickness of between 10 and 100 nm, even more preferably between 20 and 60 nm.

The etch stop layer may protect the substrate and/or the base layer, especially in the case of etching by chemical screen printing.

Thanks to the etch stop layer, the base layer remains present even in the patterned (i.e. etched) zones. In addition, migration of alkali metals, by the edge effect, between the substrate in a patterned zone and an adjacent electrode part (or even an organic structure) can be stopped.

Most particularly, for the sake of simplicity, the etch stop layer may form part of or be the base layer. Preferably, it may be based on silicon nitride or may be a layer which is based on silicon oxide or based on silicon oxynitride or based on silicon oxycarbide or else based on silicon oxycarbonitride, and with tin for reinforcement by anti-etching property, layer of general formula SnSiOCN.

Most particularly, a base/etch stop layer (essentially) made of silicon nitride Si₃N₄, whether doped or not, may be preferred. Silicon nitride is very rapidly deposited and forms an excellent alkali metal barrier, as already indicated. Furthermore, thanks to its high optical index relative to the carrier substrate, it allows the optical properties of the electrode to be adapted, preferably by varying the thickness of this base/etch stop layer. Thus, it is possible for example to adjust the colour in transmission when the electrode is transparent or the colour in reflection when the opposite side of the carrier substrate is a mirror.

The contact layer may preferably be directly beneath the silver-based functional layer (excluding the optional thin blocking layer) and serve as adhesion and/or wetting layer for the functional layer.

The contact layer may preferably be based on at least one of the following stoichiometric or non-stoichiometric metal oxides: chromium oxide, indium oxide, zinc oxide, aluminium oxide, titanium oxide, molybdenum oxide, zirconium oxide, antimony oxide, tantalum oxide, silica oxide, or even tin oxide.

Typically, the metal oxide may be doped between 0.5 and 5%. In particular, it is tin oxide doped by Al (AZO), Ga (GZO), or B, Sc, or Sb for better stability of the deposition process, or even tin oxide doped with F or S.

The contact layer may be based on a mixed oxide, especially a mixed tin zinc oxide SnₓZn_{y}O_{z}, which is generally non-stoichiometric and of amorphous phase, or based on a mixed indium tin oxide (ITO) or a mixed indium zinc oxide (IZO).

The contact layer may be a monolayer or a multilayer. Preferably, this layer has a total thickness between 3 and 30 nm or even more preferably between 5 and 20 nm.

It is preferable to choose a layer that is not toxic and is easy and/or rapid to produce, optionally transparent if necessary, especially a doped or undoped layer based on ITO, IZO, SnₓZn_{y}O_{z} or ZnOₓ.

More preferably still, a layer is chosen which is of crystalline nature along a preferential growth direction in order to promote heteroepitaxy of the silver-based functional metallic layer.

Thus, a layer of zinc oxide ZnOₓ is preferred, preferably with x less than 1, and even more preferably between 0.88 and 0.98, especially between 0.90 and 0.95. This layer may be pure or doped with Al or Ga, as already indicated.

In a preferred design of the invention, to further prevent corrosion of the functional layer, the electrode may include, between the functional layer and the overlayer, a layer based on a metal oxide for protection against oxygen and/or water, most particularly when the overlayer is thin (20 nm or less).

The protective layer may preferably be based on at least one of the following metal oxides: indium oxide, zinc oxide, aluminium oxide, titanium oxide, zirconium oxide, tantalum oxide, silicon oxide, tin oxide.

The metal oxide may typically be doped between 2 and 5%. It is in particular S-doped tin oxide or doped zinc oxide ZnO(x), for example doped with Al (AZO) for better stability or with Ga (GZO) for increasing the conductivity, or doped with B, Sc or Sb.

The protective layer may be based on a mixed oxide, especially a mixed tin zinc oxide SnₓZn_{y}O_{z}, which is generally non-stoichiometric and of amorphous phase, or a mixed indium tin oxide (ITO) or a mixed indium zinc oxide (IZO).

The protective layer may be a monolayer or a multilayer. This layer preferably has a total thickness between 3 and 90 nm, more preferably between 5 and 30 nm.

Of course, the addition of this layer dedicated to protection allows greater freedom in the choice of the overlayer chosen solely to have optimum surface properties, especially for matching the work surface for OLEDs.

It is preferable to choose a protective layer that is easy and/or rapid to produce and is transparent, especially a doped or undoped layer based on ITO, IZO, SnₓZn_{y}O_{z} or ZnOₓ.

Particularly preferable to have a layer based on zinc oxide ZnOₓ, with x preferably less than 1, preferably between 0.88 and 0.98, especially between 0.9 and 0.95. This layer may be pure or doped, as already indicated. This layer is most particularly suitable for being directly on the functional layer without degrading its transparency or its electrical conductivity.

In a preferred embodiment of the invention, the contact layer and the protective layer are of the same nature, in particular made of pure, doped or alloyed zinc oxide, and preferably the overlayer is made of ITO.

The total thickness (with the base layer) may be between 30 nm and 250 nm, or even 150 nm.

The stack of thin layers forming the electrode coating is preferably a functional monolayer coating, i.e. having a single functional layer; however, it may have functional multilayers and in particular functional bilayers.

Between the silver-based functional layer and the overlayer, the electrode may include, in succession: a separating layer based on a metal oxide optionally comprising said protective layer, said smoothing layer, a second contact layer (in particular similar to the contact layer or at the every least made of the materials already mentioned), a second silver-based functional layer (especially similar to the functional layer) and an optional blocking coating (especially similar to the optional blocking coating or at the very least made of the abovementioned materials).

The electrode may be obtained by a succession of deposition operations carried out by a vacuum technique, such as sputtering, optionally magnetron sputtering. It is also possible to provide one or even two very thin coatings called “blocking coatings” deposited directly beneath or on each side of each functional metallic layer, especially based on silver, the coating subjacent to the functional layer, in the direction of the substrate, as bonding, nucleating and/or protective coating, and the coating superjacent to the functional layer as protective or “sacrificial” coating so as to prevent impairment of the functional metallic layer by attack and/or migration of oxygen from a layer that surmounts it, or also by migration of oxygen if the layer that surmounts it is deposited by sputtering in the presence of oxygen.

The functional metallic layer may thus be placed directly on at least one subjacent blocking coating and/or directly beneath at least one superjacent blocking coating, each coating having a thickness preferably between 0.5 and 5 nm.

Within the context of the present invention, when it is specified that a deposit of a layer or coating (comprising one or more layers) is formed directly beneath or directly on another deposit, there may be no interposition of any layer between these two deposits.

At least one blocking coating preferably comprises a metallic, metal nitride and/or metal oxide layer, based on at least one of the following metals: Ti, V, Mn, Fe, Co, Cu, Zn, Zr, Hf, Al, Nb, Ni, Cr, Mo, Ta, W, or based on an alloy of at least one of said materials.

For example, a blocking coating may consist of a layer based on niobium, tantalum, titanium, chromium or nickel or on an alloy formed at least two of said metals, such as a nickel-chromium alloy.

A thin blocking layer forms a protective or even a “sacrificial” layer, which prevents impairment of the metal of the functional metallic layer, especially in one or more of the following configurations:
if the layer that surmounts the functional layer is deposited using a reactive (oxygen, nitrogen, etc.) plasma, for example if the oxide layer that surmounts it is deposited by sputtering;
if the composition of the layer that surmounts the functional layer is liable to vary during industrial fabrication (variation in the deposition conditions, of the target wear type, etc.), especially if the stoichiometry of an oxide and/or nitride type varies, therefore modifying the quality of the functional layer and therefore the properties (surface resistance, light transmission, etc.) of the electrode; and
if the electrode coating undergoes a heat treatment after deposition.

This protective or sacrificial layer significantly improves the reproducibility of the electrical and optical properties of the electrode. This is very important for an industrial approach in which only a small scatter in the properties of the electrodes is acceptable.

A thin blocking layer based on a metal chosen from niobium Nb, tantalum, Ta, titanium, Ti, chromium Cr or nickel Ni, or based on an alloy formed from at least two of these metals, especially a niobium/tantalum (Nb/Ta) alloy, a niobium/chromium (Nb/Cr) alloy or a tantalum/chromium (Ta/Cr) alloy or a nickel/chromium (Ni/Cr) alloy, is particularly preferred. This type of layer based on at least one metal has a particularly strong gettering effect.

A thin metallic blocking layer may be easily fabricated without impairing the functional layer. This metallic layer may preferably be deposited in an inert atmosphere (i.e. into which no oxygen or nitrogen has been intentionally introduced), consisting of a noble gas (He, Ne, Xe, Ar, Kr). It is neither excluded nor is it problematic for this metallic layer to be oxidized on the surface during subsequent deposition of a layer based on a metal oxide.

Such a thin metallic blocking layer also provides excellent mechanical behavior (especially abrasion and scratch resistance). This is especially so for stacks that undergo a heat treatment, and therefore a substantial diffusion of oxygen or nitrogen during this treatment.

However, for the use of a metallic blocking layer it is necessary to limit the thickness of the metallic layer and therefore the light absorption in order to retain sufficient light transmission for the transparent electrodes.

The thin blocking layer may be partially oxidized. This layer is deposited in non-metallic form and is therefore not deposited in stoichiometric form but in substoichiometric form, of the MOₓ type, where M represents the material and x is a number lower than that for stoichiometry of the oxide of the material, or of the MNOₓ type for an oxide of two materials M and N (or of more than two). For example, mention may be made of TiOₓ and NiCrOₓ.

Preferably, x is between 0.75 times and 0.99 times the normal number for stoichiometry of the oxide. For a monoxide, x may in particular be chosen to be between 0.5 and 0.98 and for a dioxide x may be between 1.5 and 1.98.

In one particular variant, the thin blocking layer is based on TiOₓ in which x may in particular be such that 1.5≦x≦1.98 or 1.5<x<1.7, or even 1.7≦x≦1.95.

The thin blocking layer may be partially nitrided. It is therefore not deposited in stoichiometric form but in substoichiometric form of the type MN_{y}, where M represents the material and y is a number smaller than that for stoichiometry of the nitride of the material, y being preferably between 0.75 times and 0.99 times the number for normal stoichiometry of the nitride.

Likewise, the thin blocking layer may also be partially oxynitrided.

This thin oxidized and/or nitrided blocking layer may be readily fabricated without impairing the functional layer. It is preferably deposited using a ceramic target in a non-oxidizing atmosphere consisting preferably of a noble gas (He, Ne, Xe, Ar, Kr).

The thin blocking layer may preferably be made of a substoichiometric nitride and/or oxide in order to further increase the reproducibility of the electrical and optical properties of the electrode.

The chosen thin substoichiometric oxide and/or nitride blocking layer may preferably be based on a metal chosen from at least one of the following metals: Ti, V, Mn, Fe, Co, Cu, Zn, Zr, Hf, Al, Nb, Ni, Cr, Mo, Ta, W, or on an oxide of a substoichiometric alloy based on at least one of these materials.

Particularly preferred is a layer based on an oxide or oxynitride of a metal chosen from niobium Nb, tantalum Ta, titanium Ti, chromium Cr or nickel Ni or on an alloy formed from at least two of these metals, especially a niobium/tantalum (Nb/Ta) alloy, a niobium/chromium (Nb/Cr) alloy, a tantalum/chromium (Ta/Cr) alloy or a nickel/chromium (Ni/Cr) alloy.

As substoichiometric metal nitride, it is also possible to choose a layer made of silicon nitride SiNₓ or aluminium AlNₓ or chromium nitride CrNₓ or titanium nitride TiNₓ or a nitride of several metals, such as NiCrNₓ.

The thin blocking layer may have an oxidation gradient, for example M(N)Oₓᵢ, with xᵢ varying, that part of the blocking layer in contact with the functional layer being less oxidized than that part of this layer furthest away from the functional layer, using a particular deposition atmosphere.

The blocking coating may also be a multilayer and in particular comprise:
on the one hand, an “interfacial” layer immediately in contact with said functional layer, this interfacial layer being made of a material based on a non-stoichiometric metal oxide, nitride or oxynitride, such as those mentioned above;
on the other hand, at least one layer made of a metallic material, such as those mentioned above, this layer being immediately in contact with said “interfacial” layer.

The interfacial layer may be an oxide, nitride or oxynitride of a metal or metals, present in the optional adjacent metallic layer.

The invention also relates to an organic light-emitting device comprising at least one carrier layer, especially made of glass, provided with:
a discontinuous lower electrode as described above, thus forming at least one row of lower electrode zones;
at least one discontinuous layer made of one or more organic electroluminescent materials in the form of electroluminescent layer zones arranged on the electrode zones; and
a discontinuous upper electrode having an electroconductive layer in the form of electrode zones arranged on the electroluminescent layer zones.

And, for a series connection of the row, the electroluminescent layer zones are offset from the lower electrode zones in the direction of the row and the lower electrode zones are offset from the electroluminescent layer zones in the direction of the row.

It will be recalled that in a series connection, the current flows from an upper electrode zone to the adjacent lower electrode zone.

The lower electrode may form a single row of lower electrode zones along the direction perpendicular to this row, and the upper electrode and the electroluminescent layer may be discontinuous in order to form a plurality of parallel rows.

Thus, the device may advantageously be organized in a plurality of substantially parallel electroluminescent rows spaced apart by at least 0.5 mm, each row being able to be connected in series.

The distance between the electroluminescent zones of separate rows may be greater than the distance between the zones of a given row, preferably above 100 μm, especially between 100 μm and 250 μm.

Each row may thus be independent. If one of the zones in each row is defective, the entire row nevertheless operates. The adjacent rows are intact.

Alternatively, the lower electrode may comprise a plurality of lower electrode zone rows and the electroluminescent layer and the upper electrode reproduce these rows (as offset along the direction of the rows).

Various types of connection are possible:
a single series connection of all of the electroluminescent zones;
a combination of series and parallel connections;
series connections specific to each row.

In a preferred embodiment, electrical connection pads in the form of an electroconductive layer made of a material identical to the upper electrode material are in connection with peripheral edges of lower electrode zones, optionally covering a subjacent insulating resin.

The organic light-emitting device according to the invention may or may not be provided with current leads.

Two continuous or discontinuous current lead bands forming part of a current collector or distributor may be respectively in electrical contact with peripheral edges of lower electrode zones, preferably via connection pads, and with peripheral edges of upper electrode zones.

The current lead bands may preferably have a thickness between 0.5 and 10 μm and a width of 0.5 mm, and may be of various forms:
a metallic monolayer made of one of the following metals: Mo, Al, Cr, Nd or an alloy of metals, such as MoCr, AlNd;
a metallic multilayer formed from the following metals: Mo, Al, Cr, Nd, such as MoCr/Al/MoCr;
preferably made of a conductive enamel, for example containing silver and screen-printed;
preferably made of a conductive material or a material filled with conductive particles and deposited by inkjet, for example a silver ink such as the ink TEC PA 030™ from InkTec Nano Silver Paste Inks; and
made of a conductive polymer whether doped or not by metals, for example silver.

It is also possible to use a thin metallic layer called a TCC (Transparent Conductive Coating) for example made of Ag, Al, Pd, Cu, Pd, Pt, In, Mo, Au and typically having a thickness between 5 and 50 nm depending on the desired light transmission/ reflection.

The upper electrode may be an electroconductive layer advantageously chosen from metal oxides, especially the following materials: doped zinc oxide, especially aluminium-doped zinc oxide ZnO:Al or gallium-doped zinc oxide ZnO:Ga, or else doped indium oxide, especially tin-doped indium oxide (ITO) or zinc-doped indium oxide (IZO).

More generally, it is possible to use any type of transparent electroconductive layer, for example a TCO (transparent conductive oxide) layer, for example with a thickness between 20 and 1000 nm.

The OLED device may produce monochromatic, especially blue and/or green and/or red, light or may be adapted so as to produce white light.

To produce white light, several methods are possible: mixing of compounds (red, green, blue emission) in a single layer; stacking on the face of the electrodes of three organic structures (red, green and blue emission) or two organic structures (yellow and blue); series of three organic adjacent organic structures (red, green, blue emission) on the face of the electrodes, one organic structure in one color and on the other face of the suitable phosphor layers.

The OLED device may comprise a plurality of adjacent organic light-emitting systems, each emitting white light, or by a series of three, emitting red, green and blue light, the systems being for example connected in series.

Each row may for example emit in a given color.

The device may form part of a multiple glazing unit, especially a vacuum glazing unit or one with an air layer or layer of another gas. The device may also be monolithic and comprise a monolithic glazing unit in order to be more compact and/or lighter.

The OLED system may be bonded to, or preferably laminated with another flat substrate, called a cover, preferably transparent, such as a glass, using a laminating interlayer, especially an extra-clear interlayer.

The laminated glazing units usually consist of two rigid substrates between which a thermoplastic polymer sheet or superposition of such sheets is placed. The invention also includes what are called “asymmetric” laminated glazing units using in particular a rigid carrier substrate of the glass type and, as a covering substrate, one or more protective polymer sheets.

The invention also includes laminated glazing units having at least one interlayer sheet based on a single-sided or double-sided adhesive polymer of the elastomer type (i.e. one not requiring a lamination operation in the conventional meaning of the term, i.e. lamination requiring heating generally under pressure so as to soften the thermoplastic interlayer sheet and make it adhere).

In this configuration, the means for fastening the cover to the carrier substrate may then be a lamination interlayer, especially a sheet of thermoplastic, for example polyurethane (PU), polyvinyl butyral (PVB) or ethylene/vinyl acetate (EVA), or a thermally curable single-component or multi-component resin (epoxy, PU) or ultraviolet-curable single-component or multi-component resin (epoxy, acrylic resin). Preferably, a sheet has substantially the same dimensions as the cover and the substrate.

The lamination interlayer may prevent the cover from flexing, especially for large devices, for example with an area greater than 0.5 m².

In particular, EVA offers many advantages:
it contains little or no water by volume;
it does not necessarily require high pressure for processing it.

A thermoplastic lamination interlayer may be preferred to a cover made of cast resin as it is both easier to implement and less expensive and is possibly more impervious.

The interlayer optionally includes an array of electroconductive wires set into its internal surface, facing the upper electrode, and/or an electroconductive layer or electroconductive bands on the internal surface of the cover.

The OLED system may preferably be placed inside the double glazing unit, especially with an inert gas (for example argon) layer.

Furthermore, it may be advantageous to add a coating having a given functionality on the opposite face from the substrate bearing the electrode according to the invention or on an additional substrate. This may be an anti-fogging layer (using a hydrophilic layer), an anti-fouling layer (a photocatalytic coating comprising TiO₂, at least partly crystallized in anatase form), or else an anti-reflection coating for example of the Si₃N₄/SiO₂/Si₃N₄/SiO₂ type, or else a UV filter such as, for example, a layer of titanium oxide (TiO₂). It may also be one or more phosphor layers, a mirror layer or at least one scattering light extraction layer.

The invention also relates to the various applications to which these OLED devices may be put, said devices forming one or more luminous surfaces, which are transparent and/or reflecting (mirror function), placed both for outdoor and indoor applications.

The device may form, alternatively or in combination, an illuminating, decorative, architectural etc. system, or an indicating display panel—for example of the drawing, logo or alpha-numeric indication type, especially an emergency exit panel.

The OLED device may be arranged to produce uniform light, especially for homogeneous illumination, or to produce various luminous zones, of the same intensity or of different intensity.

Conversely, differentiated illumination may be sought. The organic light-emitting system (OLED) produces a direct light zone, and another luminous zone is obtained by extraction of the OLED radiation that is guided by total reflection in the thickness of the substrate, which is chosen to be made of glass.

To form this other luminous zone, the extraction zone may be adjacent to the OLED system or on the other side from the substrate. The extraction zone or zones may serve for example to increase the illumination provided by the direct light zone, especially for architectural illumination, or else for indicating the luminous panel. The extraction zone or zones are preferably in the form of one or more, especially uniform, bands of light and these preferably being placed on the periphery of one of the faces. These bands may for example form a highly luminous frame.

Extraction is achieved by at least one of the following means placed in the extraction zone: a light-diffusing layer, preferably based on mineral particles and preferably with a mineral binder; a substrate made to be light-diffusing, especially a textured or rough substrate.

The two main faces may each have a direct light zone.

When the electrodes and the organic structure of the OLED system are chosen to be transparent, an illuminating window may in particular be produced. Improvement in illumination of a room is then not to the detriment of light transmission. By also limiting the light reflection, especially on the external side of the illuminating window, it is also possible to control the level of reflection, for example so as to meet the anti-dazzling standards in force for the walls of buildings.

More broadly, the device, especially a partly or entirely transparent device, may be:
intended for buildings, such as exterior luminous glazing, an internal luminous partition or a luminous glazed door (or part of a door), especially a sliding one;
intended for a transport vehicle, such as a luminous roof, a luminous side window (or part of a window), an internal luminous partition of a terrestrial, water-borne or airborne vehicle (car, lorry, train, aeroplane, boat, etc.);
intended for urban or professional furniture, such as a bus shelter panel, a wall of a display counter, a jewellery display or a shop window, a greenhouse wall, or an illuminating tile;
intended for interior furnishings, a shelf or cabinet element, a façade of a cabinet, an illuminating tile, a ceiling, an illuminating refrigerator shelf, an aquarium wall;
intended for the backlighting of electronic equipment, especially a display screen, optionally a double screen, such as a television or computer screen, a touch-sensitive screen.

For example, it is possible to envisage backlighting for a double-sided screen with various sizes, a small screen preferably being associated with a Fresnel lens to concentrate the light.

To form an illuminating mirror, one of the electrodes may be reflecting, or a mirror may be placed on the opposite face to the OLED system, if preferential lighting on only one side in the direct light zone is desired.

It may also be a mirror. The luminous panel may serve for illuminating a bathroom wall or a kitchen worktop, or maybe a ceiling.

The OLEDs are generally divided into two broad families depending on the organic material used.

If the electroluminescent layers are formed from small molecules, the devices are referred to as SM-OLED (Small-Molecule Organic Light-Emitting Diodes). The organic electroluminescent material of the thin layer consists of evaporated molecules, such as for example those of the complex AlQ₃ (tris(8-hydroxyquinoline)aluminium), DPVBi (4,4′-(diphenylvinylene)biphenyl), DMQA (dimethyl quinacridone) or DCM (4-(dicyanomethylene)-2-methyl-6-(4-dimethylaminostyryl)-4H-pyran). The emissive layer may also for example be a layer of TCTA (4,4′,4″-tri(N-carbazolyl) triphenylamine) doped with Ir(ppy)₃ (fac-tris(2-phenylpyridine)iridium).

In general, the structure of an SM-OLED consists of a stack of an HIL (hole injection layer) and a hole transporting layer (HTL), an emissive layer and an ETL (electron transporting layer).

An example of a hole injection layer is copper phthalocyanine (CuPC) and the hole transporting layer may for example be N,N′-bis(naphth-1-yl)-N,N′-bis(phenyl)benzidine (alpha-NPB).

The electron transporting layer may be composed of AlQ₃ (tris-(8-hydroxyquinoline)aluminium) or BPhen (bathophenanthroline).

The upper layer may be an Mg/Al or LiF/Al layer.

Examples of organic light-emitting stacks are for example described in document U.S. Pat. No. 6,645,645.

If the organic electroluminescent layers are polymers, the devices are referred to as PLEDs (polymer light-emitting diodes).

The organic electroluminescent material of the thin layer consists of CES polymers (PLEDs) such as for example PPV standing for poly(para-phenylenevinylene), PPP (poly(para-phenylene)), DO-PPP (poly(2-decyloxy-1,4-phenylene)), MEH-PPV (poly[2-(2′-ethylhexyloxy)-5-methoxy-1,4-phenylenevinylene]), CN-PPV (poly[2,5-bis(hexyloxy)-1,4-phenylene-(1-cyanovinylene)]) or PDAFs (polydialkylfluorenes), and the polymer layer is also associated with a layer that promotes hole injection (an HIL) consisting for example of PEDT/PSS (poly(3,4-ethylene-dioxythiophene)/poly(4-styrene sulphonate)).

One example of a PLED consists of the following stack:
a layer of poly(2,4-ethylene dioxythiophene) doped with poly(styrene sulphonate) (PEDOT:PSS) with a thickness of 50 nm; and
a layer of phenyl poly(p-phenylenevinylene) Ph-PPV with a thickness of 50 nm.

The upper electrode may be a layer of Ca.

The invention also relates to a process for fabricating the discontinuous lower electrode as defined above, comprising:
an etching step, without photolithography, for forming the lower electrode zones as one or more parallel rows; and
a step of filling between the electrode zones and extending beyond the edges of the electrode zones with screen-printed and/or with inkjet insulating resin (polymeric organic material being preferred).

This process is rapid, inexpensive and reliable.

The etching step without photolithography may comprise (or consist of):
laser etching or undermasking;
and/or chemical screen-printing with an acid etching paste, for example using the ink HiperEtch™ 04S isishape™ sold by Merck.

Laser ablation etching may be preferably used when the minimum distance is equal to or greater than 150 μm. The undermasking by screen-printing is preferred if the zones to be etched are larger than 100 μm. Undermasking using an inkjet is preferred if the zones to be etched are narrower than 100 μm.

The process may also include a step of fabricating one or more current lead bands, for example by screen-printing or by inkjet printing, as already indicated.

The invention also relates to the process the organic light-emitting device, which comprises:
a step of forming said discontinuous lower electrode as one or more parallel rows as defined above; and
a step of forming the electroluminescent zones by deposition of the electroluminescent material or materials on a mask in the form of an array organized in lines, for example metals such as aluminium or ferroelectric materials (chrome, nickel, etc.), along first and second crossed directions, the lines along the second direction being thicker.

This mask may for example be made from a metal sheet, which is produced for example by electrogravure printing.

The thick lines increase the rigidity of the thin lines intended for creating the intra-row spaces. This facilitates alignment and limits the risk of short circuits.

Advantageously, during the step of forming the upper electrode zones, the process may include the formation of electrical connection pads in the peripheral lower electrode zones of a separate row, by deposition of the upper electrode material or materials.

The invention will now be described in greater detail by means of non-limiting examples and figures:

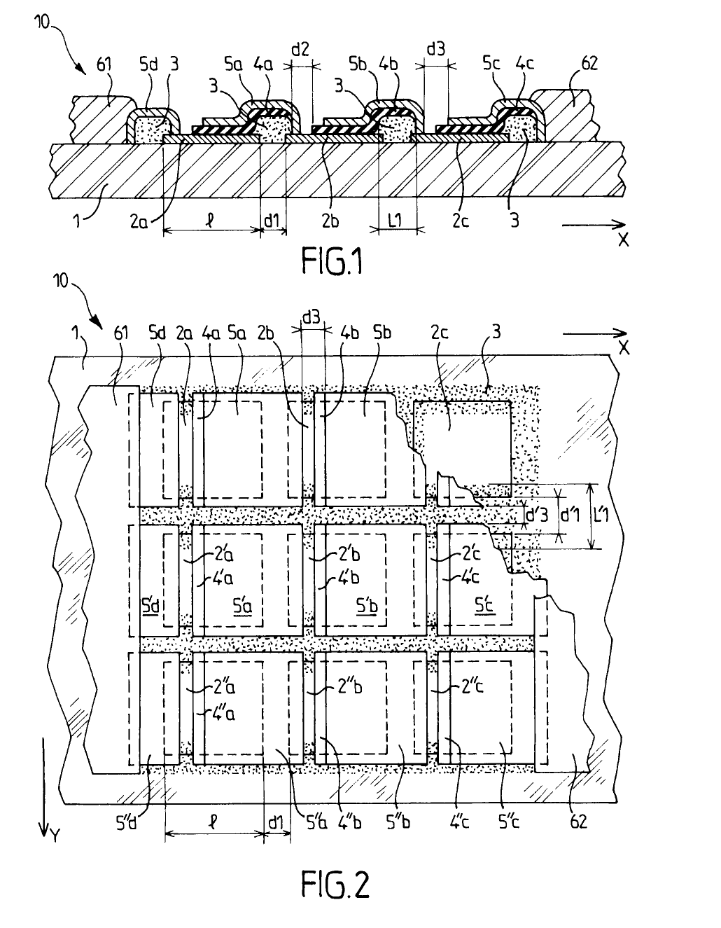

FIG. 1 is a schematic sectional view of an organic light-emitting device, which includes a lower electrode according to the invention; and

FIG. 2 illustrates a schematic top view of the device of FIG. 1.

For the sake of clarity, it should be mentioned that the various elements of the objects (including the angles) shown are not drawn to scale.

FIG. 1, which is intentionally highly schematic, shows in cross section an organic light-emitting device 10 (with emission through the substrate or “bottom emission” device). FIG. 2 illustrates a schematic top view of the device 10.

The organic light-emitting device 10 comprises a flat clear or extra-clear sodo-lime-silica glass substrate 1 having a thickness of 0.7 mm, provided on one of its main faces with, in succession:
a multilayer lower electrode 2a to 2″c, with a total thickness between 50 and 100 nm, a discontinuous electrode in the form of three parallel rows along a direction X each having three electrode zones 2a to 2c, 2′a to 2′c and 2″a to 2″c in a geometric pattern, for example squares, measuring 3 cm by 3 cm, the distance d1 (along X) between adjacent lower electrode zones of a given row being around 150 μm, the distance d′1 (along Y) between adjacent lower electrode zones of separate rows being for example identical to d1, of about 150 μm, these spaces being preferably obtained by laser etching a homogeneous electrode;
an organic light-emitting system 4a to 4″c, with a thickness of 100 nm, a discontinuous system in the form of three parallel rows along the direction X each having three electroluminescent layer zones 4a to 4c, 4′a to 4′c and 4″a to 4″c in the form of squares measuring 3 cm by 3 cm approximately (or more along Y in order to limit the edge effects, for example 10 to 20 μm more), the distance d2 (along X) between adjacent electroluminescent layer zones of a given row being less than 50 μm, for example around 25 μm, for a satisfactory fill factor; and
a discontinuous reflective upper electrode 5a to 5c, with a thickness of 200 nm, discontinuous in the form of three parallel rows along the direction X each having three upper electrode zones 5a to 5c, 5′a to 5′c and 5″a to 5″c, in the form of squares measuring 3 cm by 3 cm approximately, the distance d3 (along X) between adjacent upper electrode zones of a given row being less than 50 μm, for example around 25 μm for a satisfactory fill factor.

The spaces between the lower electrode zones 2a to 2″c and the edges of the lower electrode zones 2a to 2″c are passivated by an insulating resin 3, such as an acrylic polyamide resin, a few microns in thickness, with widths L1 along X (within a given row) and L′1 along Y (between two separate rows) equal to or greater than d1 and d′1 respectively, for example around 250 μm, the resin being deposited by screen-printing.

The distance d′2 (along Y) between adjacent electroluminescent layer zones of different rows is equal to or less than L′1, for example between 100 μm and 250 μm.

The distance d′3 (along Y) between adjacent upper electrode zones of separate rows is equal to or less than L′1, for example between 100 μm and 200 μm.

Each row is connected in series. In addition, the electroluminescent squares 4a to 4c, 4′a to 4′c and 4″a to 4″c are offset by 25 to 60 μm along X relative to the lower electrode squares 2a to 2c, 2′a to 2′c and 2″a to 2″c, and the upper electrode squares 5a to 5c, 5′a to 5′c and 5″a to 5″c are offset by 25 to 60 μm along X relative to the electroluminescent squares 4a to 4c, 4′a to 4′c and 4″a to 4″c. The current thus flows from an upper electrode zone to the adjacent lower electrode zone 5a to 2b, 5b to 2c.

A simple and reliable way of producing the electroluminescent squares consists in placing on the lower electrode, especially with the aid of reference marks on the four corners of the glass 1, a metal mask in the form of first and second perpendicular lines. The first lines are thin, with a width of less than 50 μm (giving d2), for example around 25 μm, and are positioned parallel to Y near the passivated edges.

The second lines are thicker in width (giving d′2) between 100 μm and 250 μm and are positioned parallel to X. These thick lines strengthen the first lines, straightening them, the spaces between electroluminescent zones of a given row thus being sharply defined straight lines.

One simple and reliable way of producing the upper electrode squares consists in placing the mask already used, but offset along X by 25 to 60 μm, on the electroluminescent squares.

In this example, the fill factor is about 0.98. The ratio of the brightness (measured in Cd/m²) at the centre of each illuminating square to that of any edge of this illuminating square is around 0.8. The brightness of the device 10 may be at least 1000 Cd/m².

The device is supplied with a low voltage, for example 24 V or 12 V (motor vehicle applications, etc.) and the current is around 50 mA and fluctuates little within a given range.

On one side of the glass 1, the peripheral lower electrode edges 2a, 2′a and 2″a are not covered by the electroluminescent squares and are in electrical connection with electrical connection bands 5a to 5d, for example with a width of the order of 1 cm along X and around 3 cm along Y. These connection bands 5a to 5d may be produced at the same time as the upper electrode, especially made of the same material(s).

For series and parallel connections:
a first current lead band 61, preferably with a thickness of between 0.5 and 10 μm, for example 5 μm, and with a thickness along X of 5 cm and for example in the form of a metallic layer made of one of the following metals: Mo, Al, Cr, Nd or an alloy such as MoCr, AlNd, or a multilayer such as MoCr/Al/MoCr, is formed on these connection bands 5a to 5d; and
on the other side of the glass, a second, similar current lead band 62 is formed on the peripheral edges of the upper electrode zones 5c, 5′c, 5″c.

For these series and parallel connections, d′1 may be zero.

For a series connection of all the rows, the first current lead band 61 is discontinuous between 2a and 2′a and the second current lead band 62 is discontinuous between 5′c and 5″c.

For a series connection specific to each row, the first current lead band 61 is discontinuous between 2a and 2′a, 2′a and 2″a and the second current lead band 62 is discontinuous between 5c and 5′c, 5′c and 5c.″

The discontinuous lower electrode 2a to 2″c, chosen to be transparent, comprises a multilayer stack of the type:
an adhesive contact layer chosen from doped or undoped ZnOₓ, SnₓZn_{y}O_{z}, ITO or IZO;
a functional layer, preferably made of pure silver;
a protective layer chosen from ZnOₓ, SnₓZn_{y}O_{z}, ITO or IZO, the contact layer and the layer for protecting against water and/or oxygen being of the same nature; and
a work-function-matching overlayer, i.e. preferably the stack ZnO:Al/Ag/ZnO:Al/ITO with respect to thicknesses of 5 to 20 nm for the ZnO:Al, 5 to 15 nm for the silver, 5 to 20 nm for the ZnO:Al and 5 to 20 nm for the ITO.

The lower electrode 2a to 2″c has the following characteristics:
a surface resistance equal to or less than 5 Ω/□
a light transmission T_{L} equal to or greater than 70% (measured on a complete layer, before structuring) and a light reflection R_{L} equal to or less than 20%;
an RMS roughness (or R_{q}) equal to or less than 3 nm measured by optical interferometry on a square micron by atomic force microscopy.

A silicon nitride base layer with a thickness between 10 nm and 80 nm may be between the lower electrode 2a to 2″c and the substrate 1.

For an Si₃N_{4 20 nm}/ZnO:Al_{20 nm}/Ag_{12 nm}/ZnO:Al_{40 nm}/ITO_{20 nm} stack, a T_{L} of 75%, an R_{L} of 15%, a surface resistance of 4.5 ohms/□ and an RMS roughness of 1.2 nm are obtained.

For an Si₃N_{4 20 nm}/SnZnSb:Ox_{5 nm}/ZnO:Al_{5 nm}/Ag_{12 nm}/Ti_{1 nm}/ZnO:Al_{20 nm}/ITO_{20 nm} stack, a T_{L} of 85%, an R_{L} of 8%, a surface resistance of 3.3 ohms/□ and an RMS roughness of 0.7 nm are obtained.

For an Si₃N_{4 20} nm/SnZnSb:Ox_{5 nm}/ZnO:Al_{5 nm}/Ag_{12 nm}/Ti_{0.5 nm}/ITO_{20 nm} stack, a T_{L} of 65%, an R_{L} of 29%, a surface resistance of 3.3 ohms/□ and an RMS roughness of 0.7 nm are obtained.

The SnZn:SbOₓ-based layers are deposited by reactive sputtering using an antimony-doped tin and zinc target, comprising, by weight, 65% Sn, 34% Zn and 1% Sb, under a pressure of 0.2 Pa and in an argon/oxygen atmosphere.

The Ti layers are deposited using a titanium target under a pressure of 0.8 Pa in a pure argon atmosphere.

The lower electrode 2a to 2″c may as a variant also be a semi-transparent electrode. For Si₃N_{4 20 nm}/ZnO:Al_{20 nm}/Ag_{30 nm}/ZnO:Al_{40 nm}/ITO_{20 nm}, a T_{L} of 16%, an R_{L} of 81% and a surface resistance of 0.9 ohms/□ are obtained.

The discontinuous organic light-emitting system 4a to 4″c is for example an SM-OLED of the following structure:
a layer of alpha-NPD;
a layer of TCTA+Ir(ppy)₃;
a layer of BPhen; and
a layer of LiF.

The discontinuous reflecting upper electrode 5a to 5c may in particular be metallic, especially based on silver or aluminium.

All the layers 2, 4 and 5 were deposited by magnetron sputtering at ambient temperature.

An EVA sheet may be used to laminate the glass 1 to another glass, preferably having the same characteristics as the glass 1. Optionally, that face of the glass turned towards the EVA sheet is provided with a stack of given functionality.

It goes without saying that the invention applies in the same manner when using organic light-emitting systems other than those described in the example.

1. A substrate, for an organic light-emitting device bearing a discontinuous electrode on a main face comprising, in succession, starting from the substrate:
a contact layer based on a metal oxide;
a metallic functional layer having an intrinsic electrical conductivity property, based on silver, the functional layer thickness being less than 100 nm; and
a work-function-matching overlayer,
the electrode having a surface resistance equal to or less than 5 Ω/□ and
the electrode being in the form of at least one row of electrode zones, with electrode zones having a first dimension (l) of at least 3 cm in the direction (X) of said row, the electrode zones of the row being spaced apart by a distance equal to or less than 0.5 mm, and insulating material filling the space between the electrode zones and projecting beyond the electrode zones.

2. The substrate for an organic light-emitting device according to claim 1, wherein the insulating material is screen-printed, or is an insulating ink deposited by an ink jet, wherein the insulating material covers the peripheral edges of the electrode zones.

3. The substrate for an organic light-emitting device according to claim 1, wherein the discontinuous electrode is obtained without photolithography, by laser etching, by chemical screen-printing with an etching paste, or by masking with a mask made of screen-printed or inkjet deposited material.

4. The substrate for an organic light-emitting device according to claim 1, wherein the surface resistance is equal to or less than 5 Ω/□ for a functional layer thickness equal to or less than 20 nm and a light transmission T_{L} equal to or greater than 60% and an absorption factor A of less than 10%.

5. The substrate for an organic light-emitting device according to claim 1, wherein the metallic functional layer is based on pure silver or silver alloyed or doped with Au, Pd, Al, Pt, Cu, Zn, Cd, In, Si, Zr, Mo, Ni, Cr, Mg, Mn, Co or Sn.

6. The substrate for an organic light-emitting device according to claim 1, wherein the overlayer has a thickness between 3 and 50 nm and is based on at least one of the following, optionally doped, metal oxides: chromium oxide, indium oxide, optionally substoichiometric zinc oxide, aluminium oxide, titanium oxide, molybdenum oxide, zirconium oxide, antimony oxide, tin oxide, tantalum oxide and silicon oxide.

7. The substrate for an organic light-emitting device according to claim 1, wherein the overlayer is made of ITO with a thickness equal to or less than 30 nm.

8. The substrate for an organic light-emitting device according to claim 1, wherein the contact layer is based on a doped or undoped metal oxide.

9. The substrate for an organic light-emitting device according to claim 1, wherein the functional metallic layer is deposited directly on at least one subjacent blocking coating which is on the contact layer and/or directly under at least one superjacent blocking coating.

10. The substrate according to claim 9, wherein at least one blocking coating comprises a metal, metal nitride and/or metal oxide layer based on at least one of the following metals: Ti, V, Mn, Fe, Co, Cu, Zn, Zr, Hf, Al, Nb, Ni, Cr, Mo, Ta and W, or based on an alloy of at least one of said metals.

11. The substrate according to claim 1, wherein it includes a non-crystalline smoothing layer made of a mixed oxide, said smoothing layer being disposed immediately beneath said contact layer and being made of a material other than that of the contact layer.

12. The substrate according to claim 11, wherein the smoothing layer is a mixed oxide layer based on an oxide of one or more of the following metals: Sn, Si, Ti, Zr, Hf, Zn, Ga and In.

13. The substrate according to claim 1, wherein it includes, beneath the contact layer, a base layer capable of forming a barrier to alkali metals, the material of said base layer being optionally doped and said base layer preferably having a thickness between 10 and 150 nm.

14. The substrate according to claim 1, wherein it includes, beneath the contact layer an etch stop layer.

15. The substrate according to claim 1, wherein it comprises between the functional layer and the overlayer, in succession: a separating layer based on a metal oxide optionally comprising said protective layer, said smoothing layer, a second contact layer, a silver-based second functional layer and an optional blocking coating.

16. The substrate according to claim 1, wherein electrical connection pads, in the form of an electroconductive layer made of a material identical to the upper electrode material, are in connection with peripheral edges of lower electrode zones.

17. The substrate according to claim 1, wherein the substrate is flat, and made of glass.

18. An organic light-emitting device comprising at least one carrier layer, of glass, provided with:
a discontinuous lower electrode according to claim 1, thus forming at least one row of lower electrode zones;
at least one discontinuous electroluminescent layer made of one or more organic electroluminescent materials in the form of electroluminescent layer zones arranged on the electrode zones; and
a discontinuous upper electrode having an electroconductive layer in the form of electrode zones arranged on the electroluminescent layer zones, and, for a series connection of the row, the electroluminescent layer zones are offset from the lower electrode zones in the direction (X) of the row and the lower electrode zones are offset from the electroluminescent layer zones in the direction (X) of the row.

19. The organic light-emitting device according to claim 18, wherein the device is organized as a plurality of substantially parallel electroluminescent rows spaced apart by at least 0.5 mm, each row being able to be connected in series.

20. The organic light-emitting device according to the preceding claim claim 19, wherein the distance between the electroluminescent layer zones of separate rows is greater than the distance between the zones of a given row.

21. The organic light-emitting device according to claim 18, wherein for each illuminating zone associated with an electrode zone, the ratio of the brightness (measured in Cd/m²) at the centre to that of any edge of this illuminating zone is equal to or greater than 0.7.

22. The organic light-emitting device according to claim 18, wherein electrical connection pads, in the form of an electroconductive layer made of a material identical to the upper electrode material, are in connection with peripheral edges of the lower electrode zones.

23. The organic light-emitting device according to claim 18, wherein the device is a single glazing, double glazing, multiple glazing or laminated glazing unit.

24. The organic light-emitting device according to claim 18, wherein it forms one or more transparent and/or reflective luminous surfaces, or an indicating display panel, the system producing uniform light or differentiated luminous zones, differentiated by guided light extraction in the glass substrate.

25. The organic light-emitting device according to claim 18, wherein it is:
intended for exterior luminous glazing, an internal luminous partition or a luminous glazed door of a building;
intended for a luminous roof, a luminous side window, or an internal luminous partition of a terrestrial, water-borne or airborne transpot vehicle;
intended for urban or professional furniture, a bus shelter panel, a wall of a display counter, a jewellery display or a shop window, a greenhouse wall, or an illuminating tile;
intended for interior furnishings, a shelf or cabinet element, a façade of a cabinet, an illuminating tile, a ceiling, an illuminating refrigerator shelf, or an aquarium wall;
intended for the backlighting of electronic equipment; and
intended for an illuminating mirror, for lighting a bathroom wall or a kitchen work top, or for a ceiling.

26. A process for fabricating a discontinuous electrode according to claim 1, comprising:
etching, without photolithography, for forming lower electrode zones as one or more parallel rows; and
filling between the electrode zones and extending beyond the edges of the electrode zones with screen-printed or inkjet insulating resin.

27. The process for fabricating the discontinuous electrode according to claim 26, wherein the etching step comprises screen-printing with an acid etching paste.

28. The process for fabricating the discontinuous electrode according to claim 26, wherein the etching comprises laser etching.

29. The process for fabricating the discontinuous electrode according claim 26, wherein it comprises fabricating one or more current-lead bands by screen-printing.

30. A process for fabricating an organic light-emitting device, comprises comprising:
forming a discontinuous lower electrode as one or more parallel rows, according to claim 26; and
forming electroluminescent layer zones by the deposition of an electroluminescent material or materials on a mask in the form of an array organized in lines along first and second crossed directions (X, Y), the lines along the second direction (Y) being thicker.

31. The process for fabricating the device according to claim 30, wherein it includes forming the upper electrode zones by deposition of the upper electrode material or materials on said mask offset along the first direction (X).

32. The process for fabricating the device according to claim 30, wherein, during the forming of the upper electrode zones, it includes the formation of electrical connection pads in the peripheral lower electrode zones of a separate row, by deposition of the upper electrode material or materials.
